(19) United States
(12) Patent Application Publication
(10) Pub. No.: US 2022/0389540 A1
(43) Pub. Date: Dec. 8, 2022

(54) Ultra-Conductive Metal Composite and Methods of Making the Same

(71) Applicant: MetalKraft Technologies, LLC, Albany, OH (US)

(72) Inventor: Frank F Kraft, Albany, OH (US)

(73) Assignee: MetalKraft Technologies, LLC, Albany, OH (US)

(21) Appl. No.: 17/834,876

(22) Filed: Jun. 7, 2022

Related U.S. Application Data
(60) Provisional application No. 63/197,986, filed on Jun. 7, 2021.

(51) Int. Cl. C22C 9/00; C23C 16/26; B21C 23/24

(52) U.S. Cl. CPC C22C 9/00; C23C 16/26; B21C 23/24

(57) ABSTRACT

A conductor material includes a metal matrix, and a first carbon allotrope distributed within the metal matrix, the first carbon allotrope being aligned with a direction of electric current flow through a length of the metal matrix. The metal matrix and the first carbon allotrope have an electrical interfacial coherency.

### CROSS REFERENCE TO RELATED APPLICATION

The present application claims benefit of U.S. Provisional Application No. 63/197,986, filed on Jun. 7, 2021, the contents of which are hereby incorporated by reference in their entirety for all purposes.

### BACKGROUND

Conductive materials have wide application, particularly in electric motors (such as industrial electric motors and motors used in the transportation sector) and in power-grid applications. Machine drives (such as electric motors, pumps, and fans) account for about half of the manufacturing sector's delivered electricity use and about 8% of the sector's total fuel consumption. The wide use of machine drives is a significant driver of electricity demand. Conductive materials are therefore needed in all such applications.

Conventional approaches to increasing conductivity of metals or metal composites have not been able to either achieve the increased power densities required for desired energy savings or achieve economically justified manufacturing or operating costs.

### SUMMARY

There is therefore a need for ultra-conductive metal composites to achieve energy savings and reduced climate impact for, among other applications, machine drives and other high-energy applications requiring use of conductive materials. The ultra-conductive metal composites and methods disclosed herein can achieve the increased power densities required for desired energy savings at economically justified manufacturing or operating costs.

According to one exemplary embodiment of the present disclosure, a conductor material includes a metal matrix, and a first carbon allotrope distributed within the metal matrix, the first carbon allotrope being aligned with a direction of electric current flow through a length of the metal matrix. The metal matrix and the first carbon allotrope have an electrical interfacial coherency.

According to one aspect, a defect density of the first carbon allotrope is less than a predetermined threshold. According to one aspect, the predetermined threshold for the defect density is 2.1±0.1×10¹⁰ cm⁻². According to one aspect, the predetermined threshold of the defect density is measured across the length of the metal matrix.

According to one aspect, the metal matrix comprises a metal selected from the following group: copper, aluminum, silver, or magnesium. According to one aspect, the first carbon allotrope is selected from the following group: graphene, few-layer graphene, nano-graphite particles, graphite, or carbon nano-tubes. According to one aspect, a concentration of the first carbon allotrope of the conductor material is within a range of about 0.004 to about 0.016 weight percent.

According to one aspect, the conductor material includes a second carbon allotrope distributed within the metal matrix selected from the following group: graphene, few-layer graphene, nano-graphite particles, graphite, or carbon nano-tubes. According to one aspect, a concentration of the second carbon allotrope of the conductor material is within a range of about 0.004 to about 0.016 weight percent. According to one aspect, wherein the first carbon allotrope is different from the second carbon allotrope. According to another aspect, the wherein the first carbon allotrope is the same as the second carbon allotrope.

According to one aspect, the first carbon allotrope comprises a polycrystalline structure having an average grain size of about 20 μm. According to one aspect, the second carbon allotrope comprises a polycrystalline structure having an average grain size of about 20 μm.

According to one aspect, the first carbon allotrope comprises hexagonal graphene crystals. According to one aspect, the second carbon allotrope comprises hexagonal graphene crystals.

According to one aspect, the metal matrix comprises metallic grains recrystallized to one or more first carbon allotrope particles. According to one aspect, the electrical interfacial coherency is more than a predetermined threshold.

According to another exemplary embodiment of the present disclosure, a copper composite material includes a copper matrix; and a graphene coat deposited on the copper matrix. The graphene coat forms an electrical interfacial coherency with the copper matrix. The graphene coat comprises graphene particles aligned with a direction of electric current flow along a length of the copper wire. A defect density of the graphene particles is less than about 2.1±0.1×10¹⁰ cm⁻². The graphene particles include grain boundaries having a polycrystalline structure. The graphene coat includes graphene and a carbon allotrope selected from the following group: graphene, few-layer graphene, nano-graphite particles, graphite, or carbon nano-tubes. Coherency can be achieved by re-crystallizing the copper matrix with the graphene coat.

According to one aspect, the polycrystalline structure comprises at least one pentagon-hexagon pair. According to one aspect, the polycrystalline structure comprises at least one heptagon-hexagon pair.

According to another exemplary embodiment of the present disclosure, a method for making an ultra-conductive metal composite includes the steps of providing a metal component; coating the metal component with a carbon allotrope; combining a plurality of coated metal components to form a billet assembly; hot extruding the billet assembly to form a composite strip; rolling the composite strip; and extruding the composite strip to form a final metal composite.

The method optionally includes re-coating the composite strip with a carbon allotrope after the composite strip is rolled, then re-fabricating a new billet assembly, re-extruding the new billet assembly to form a new composite strip, re-rolling the new composite strip, and repeating these optional steps (for example, repeatedly re-assembling a billet and extruding the billet into another form) until a desired concentration of the carbon allotrope is achieved by such iterative process.

According to one aspect, the step of coating the metal strip with a carbon allotrope is by a conventional deposition process (PVD, CVD, PECVD, etc.).

According to one aspect, the method also includes further processing the final metal composite. Further processing can include drawing, annealing, rolling, stranding, coating, or other such processes.

This summary is illustrative only and is not intended to be in any way limiting. Other aspects, inventive features, and advantages of the devices and/or processes described herein, as defined solely by the claims, will become apparent in the detailed description set forth herein, taken in conjunction with the accompanying figures, wherein like reference numerals refer to like elements.

### BRIEF DESCRIPTION OF THE DRAWINGS

FIG. 1 is a side view schematic of an ultra-conductive metal composite according to an aspect of the present disclosure.

FIG. 2 is a graph presenting experimental results according to the present disclosure.

FIG. 3 is a graph presenting additional experimental results according to the present disclosure.

FIG. 4 is a graph presenting still additional experimental results according to the present disclosure.

FIG. 5 is a flow chart summarizing a method of making an ultra-conductive metal composite, according to an aspect of the present disclosure.

### DETAILED DESCRIPTION

Before turning to the figures, which illustrate the exemplary embodiments in detail, it should be understood that the present disclosure is not limited to the details or methodology set forth in the description or illustrated in the figures. It should also be understood that the terminology used herein is for the purpose of description only and should not be regarded as limiting.

Referring generally to the figures, an ultra-conductive metal composite and methods of making the same are disclosed. For example, the present disclosure relates to forming a copper graphene nano-alloy having a room temperature (20° C.) electrical conductivity of 60.132 MS/m (about 103.67% IACS), along with improvements in temperature coefficient of resistivity and current density, with improvements of electrical conductivity that can be at least 109% IACS.

Electrical conductivity in metal is related to the mobility of free electrons, which are impeded or scattered by defects or impurities in the crystal lattice of the metal. Thus, a metal's conductivity increases with refinement to higher purity levels. Due to extraordinary electrical properties of carbon allotropes, embedding carbon allotropes (such as carbon nanotubes and graphene) into metals (such as copper) can achieve improved electrical properties, contrary to conventional wisdom.

The present disclosure focuses on the use of a carbon allotrope (such as graphene, a two-dimensional carbon allotrope resulting from hybridizing of the 1-s and 2-p orbitals that form hexagonal carbon rings). After sp² hybridization each carbon atom still retains a free electron which manifests in the π orbital. The π orbital contributes to a delocalized electron network and enables high charge carrier (e.g., electron) concentrations coupled with high charge carrier mobility at room temperature. This enables localized ballistic conduction of charge carrier on a near-micron scale, making it suitable for enhancing thermal and electrical properties in metals. A degree of coherency must be established at the metal-carbon allotrope interface (e.g., between the delocalized or free π and metal electrons).

As used herein, “electrical interfacial coherency” or “coherency” refers to a relationship between the metal matrix and a carbon allotrope disposed in or within or deposited on the metal matrix. For example, when micro or nano scale particles are precipitated out, the micro or nano scale particles maintain their relationship with the matrix. The electrical interfacial coherency thus refers to a relationship between the metal matrix and the carbon allotrope that is beneficial to and facilitates electron flow through the conductor material. Increased electrical interfacial coherency can be indicated by improved or increased conductivity of the conductor material at or above a predetermined threshold. For example, increased electrical interfacial coherency can be shown by a 3% increase in conductivity over a baseline of 58.001 MS/m. As another example, increased electrical interfacial coherency can be shown by a 5% increase in conductivity over a baseline of 58.001 MS/m. As yet another example, increased electrical interfacial coherency can be shown by an 8% increase in conductivity over a baseline of 58.001 MS/m. As yet another example, increased electrical interfacial coherency can be shown by a 9% increase in conductivity over a baseline of 58.001 MS/m. As yet another example, increased electrical interfacial coherency can be shown by a 10% increase in conductivity over a baseline of 58.001 MS/m.

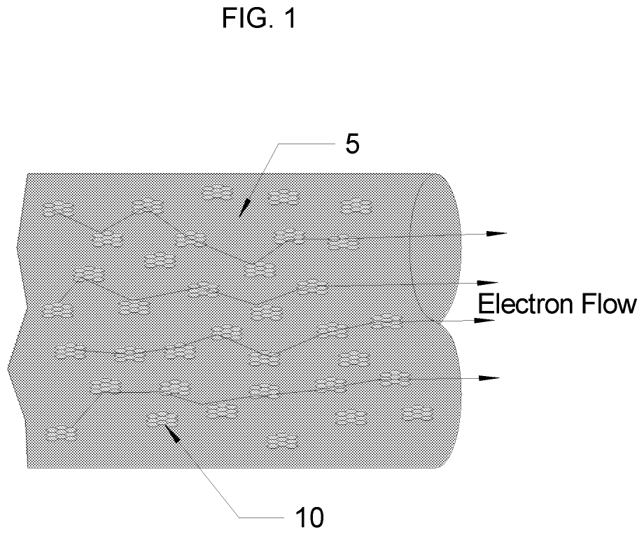

Referring now to FIG. 1, a conductor material (such as an ultra-conductive metal composite) 1 is shown. The conductor material 1 includes a metal matrix 5. The metal matrix 5 can include any suitable metal, such as such as copper, aluminum, silver, and magnesium. According to some aspects, the metal matrix includes another metal to improve mechanical properties.

The conductor material 1 also includes a first carbon allotrope 10 coated or otherwise coupled to a surface of the metal matrix 5. As described in more detail below with respect to methods of making the conductor material 1, the first carbon allotrope 10 is coated to the surface of the metal matrix 5 using any suitable process, such as any suitable deposition process (such as chemical vapor deposition). The first carbon allotrope 10 can include any suitable carbon allotrope, such as graphene, few-layer graphene, nano-graphite particles, graphite, or carbon nano-tubes.

As shown in FIG. 1, the first carbon allotrope 10 is aligned with a direction of electric current flow through a length of the metal matrix 5.

A defect density of the first carbon allotrope is less than a predetermined threshold. According to one aspect, the predetermined threshold is about 2.1±0.1×10¹⁰ cm⁻². According to another aspect, the predetermined density is threshold is not more than 2.1±0.1×10¹⁰ cm⁻². According to one aspect, the defect density is measured across an entire length of the conductor material 1. According to another aspect, the defect density is measured across only a portion of the length of the conductor material 1.

According to one aspect, a concentration of the first carbon allotrope is within a range of about 0.0001 to about 2 weight percent of the conductor material 1. According to another aspect, the concentration of the first carbon allotrope is within a range of about 0.004 to about 0.0016 weight percent of the conductor material 1. According to one aspect, the concentration of the first carbon allotrope is about 0.002 weight percent. According to one aspect, the concentration of the first carbon allotrope is about 0.004 weight percent. According to one aspect, the concentration of the first carbon allotrope is about 0.006 weight percent. According to one aspect, the concentration of the first carbon allotrope is about 0.008 weight percent. According to one aspect, the concentration of the first carbon allotrope is about 0.010 weight percent. According to one aspect, the concentration of the first carbon allotrope is about 0.012 weight percent. According to one aspect, the concentration of the first carbon allotrope is about 0.014 weight percent. According to one aspect, the concentration of the first carbon allotrope is about 0.016 weight percent. According to one aspect, the concentration of the first carbon allotrope is about 1 weight percent. According to one aspect, the concentration of the first carbon allotrope is about 2 weight percent.

The metal matrix 5 and the carbon allotrope 10 develop an electrical interfacial coherency at the metal-carbon-allotrope interface. According to one aspect, and as discussed above, an electrical interfacial coherency between the metal matrix 5 and the first carbon allotrope 10 is more than a predetermined threshold.

According to one aspect, the carbon allotrope 10 has grain boundaries having a polycrystalline structure. For example, the carbon allotrope 10 has at least one pentagon-hexagon pair or dislocation in the polycrystalline structure. As another example, the carbon allotrope 10 has at least one heptagon-hexagon pair or dislocation in the polycrystalline structure.

Optionally, the first carbon allotrope also includes a second carbon allotrope. The second carbon allotrope (not shown) can include any suitable carbon allotrope, such as graphene, few-layer graphene, nano-graphite particles, graphite, or carbon nano-tubes. According to one aspect, the second carbon allotrope is a different type from the first carbon allotrope. According to another aspect, the second carbon allotrope is the same type of carbon allotrope as the first carbon allotrope 10.

All of the properties herein described pertaining to the first carbon allotrope 10 also apply to the second carbon allotrope. For example, according to one aspect, a defect density of the second carbon allotrope is less than about 2.1±0.1×10¹⁰ cm⁻². As another example, according to one aspect, a concentration of the second carbon allotrope is within a range of about 0.0001 to about 2 weight percent of the conductor material 1 or within a range of 0.004 and 0.0016 weight percent.

Thus, according to one aspect of the present disclosure, the conductor material 1 includes the metal matrix 5 with the first carbon allotrope and the second carbon allotrope and any combination thereof.

### Exemplary Embodiment: Copper-Graphene Composite

One specific application of the ultra-conductive metal composite as disclosed herein is an ultra-conductive copper-graphene composite. For example, a high-quality, low defect graphene (such as the first carbon allotrope 10) is added into a copper matrix (such as metal matrix 5) at the requisite level and with properly engineered orientation and coherency with the metal matrix 5 (achieved through processing).

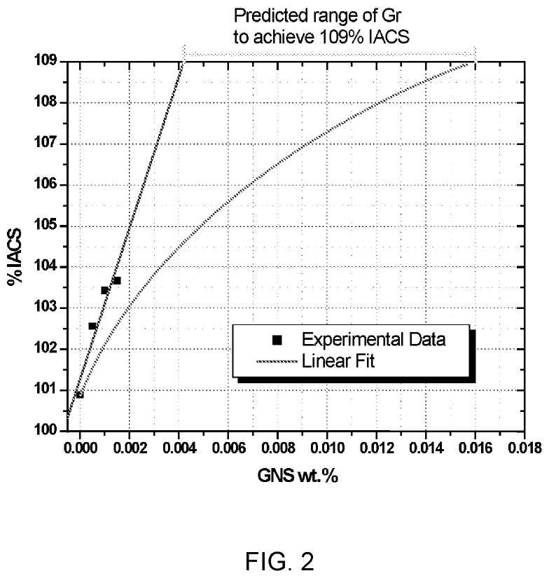

As shown in FIG. 2, experimental results of previous work and extrapolation of the expected graphene additions can achieve 109% IACS. These results were from bulk measurements made on 2 mm diameter wire over 150 mm lengths. Extrapolation to achieve 109% IACS is projected at a graphene content of approximately 0.004-0.016 weight percent, but the upper value can be even higher (such as up to 2 weight percent) to achieve even higher conductivity values.

As shown in FIG. 2, a 2.7% increase in conductivity was achieved over the control sample, which measured consistent with conductor grade copper (at 100.9% IACS). Thus, both the graphene amount and copper-graphene interface coherency developed during processing contributed to higher electrical conductivity. Higher defect graphene can also give improvements, but at lower levels of conductivity increases. Conversely, performance improvements can be achieved for copper-graphene systems in nano and micron scale samples with high quality deposited or CVD graphene. Nevertheless, it is a focus to achieve higher graphene amounts (with low defect graphene) with the requisite orientation and interfacial coherency with the copper matrix, to achieve improved electrical properties.

Additional electrical performance improvements, in temperature coefficient of resistivity and current density can also be achieved. A temperature coefficient of resistivity improvement (a lower value) corresponds to improved electrical conductivity at the elevated temperatures at which electric motors and devices generally operate. The ability of the material to pass a higher current at a specific elevated temperature (current density) is also considered. A temperature coefficient of resistivity improvement of over 25% and current density increase of over 80% can also be achieved.

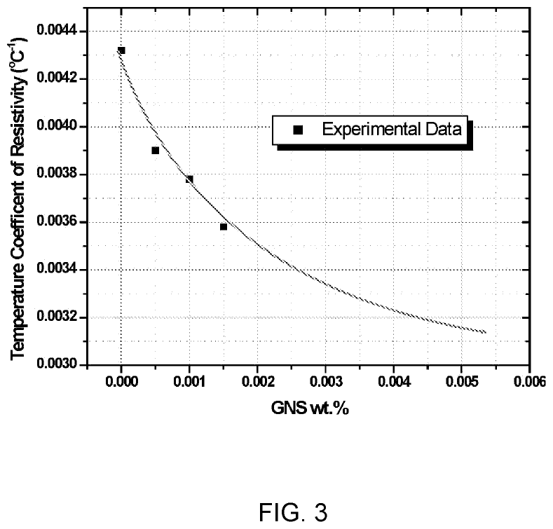

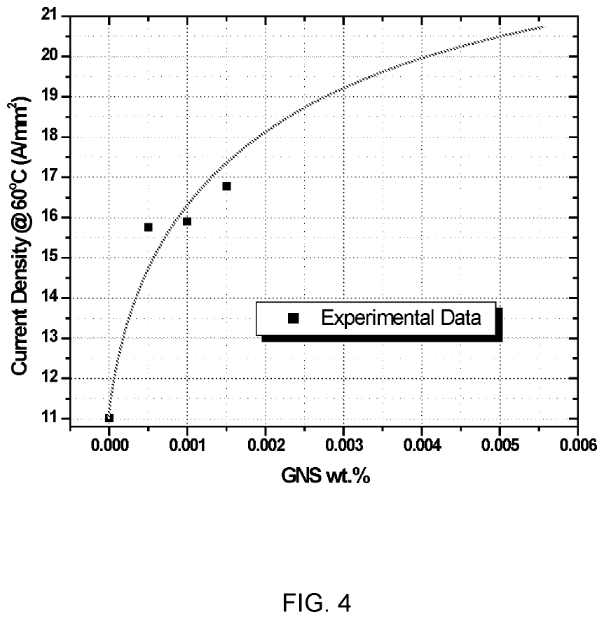

As shown in FIGS. 3 and 4, experimental data of the same wires presented in FIG. 2 show trends to achieve these improvements in temperature coefficient of resistivity and current density. The improvements exhibited by these data are a 17.1% decrease in temperature coefficient of resistivity, and a 52.3% increase in current density (at 60° C.), over a copper-only C1100 sample. The electrical performance improvements were in comparison to both control samples (made with the lab-scale approach) and conventional copper conductor wire purchased commercially (and in concert with published values).

As one example, graphene is suitable for use with a copper matrix to form a copper-graphene ultra-conductive metal composite because graphene can improve bulk scale properties. Also, CVD coated (with graphene) copper foils provide the highest quality, lowest defect precursor material to achieve improved bulk electrical conductivity in copper, and thus it is well-suited to meet the performance and cost needs in industrial and consumer applications. Although a theoretical maximum for mono-layer defect-free graphene in an Ultra High Vacuum can approach 172% IACS, this would be significantly less for graphene with impurities and defects. Thus, an ultra-conductive copper-graphene composite can achieve a conductivity goal of 109% IACS in a bulk-scale copper wire, rod, bar, or sheet, when the following characteristics are exhibited in the material:

First, high quality, low defect, crystalline graphene precursor material is an excellent option and can be more suitable than other carbon allotropes, such as carbon nano-tubes.

Second, the graphene must be reasonably well distributed within the bulk copper matrix, cohered in the requisite amount, and suitably aligned with the direction of electric current flow.

Third, carbon nano particles agglomerations must be reasonable minimized. Such agglomeration is detrimental to electrical performance if allowed to remain in the metal matrix as agglomerations. Also, porosity and oxides are detrimental and must also be avoided or at least minimized.

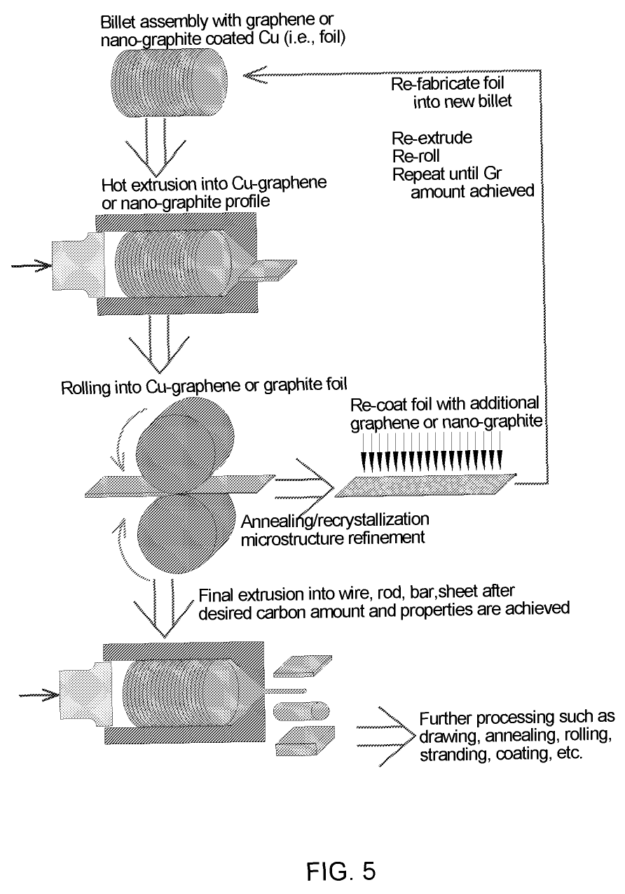

Fourth, as descried in more detail below in reference to FIG. 5, processing must promote a micro and nano structure where the mono (or possibly few) layer graphene and copper develop an “electrical interfacial coherency” while avoiding the introduction of additional defects into the graphene. Mono graphene layers uniformly distributed within the copper matrix provides the best performance at the lowest concentration, as shown in FIG. 2 (particularly when compared to higher defect graphene).

Fifth, a desired structure, morphology, and properties are only achieved with solid state processing.

These five characteristics are essential in achieving 109% IACS for a copper-based conductor, such as an ultra-conductive copper composite. The second requirement listed above has not been previously satisfied, namely achieving graphene at the requisite amount in the copper matrix. The iterative process described below is therefore an important achievement, as one skilled in the art would appreciate for making an ultra-conductive metal composite such as an ultra-conductive copper composite.

Methods of Making Ultra-Conductive Metal Composite

The methods disclosed herein are particularly suitable to bulk scale application, as one skilled in the art would appreciate. The iterative processes herein disclosed are suitable for making an ultra-conductive metal composite having desired mechanical properties, such as improved conductivity, among other properties, as one skilled in the art would also appreciate.

As shown in FIG. 5, a method for making an ultra-conductive metal composite is disclosed. The ultra-conductive metal composite can include a metal matrix made of any appropriate metal, such as copper, aluminum, silver, and magnesium. To improve the performance of the metal, other metals (such as any of the others listed above) can be included in a metal matrix.

The ultra-conductive metal composite includes additions of a carbon allotrope, such as graphene, few-layer graphene, nano-graphite particles, graphite, or carbon nano-tubes processed to improve electrical properties, such as conductivity, current density or ampacity, and thermal coefficient of resistance, as well as thermal conductivity.

As shown in FIG. 5, a precursor metal material (e.g., copper or other suitable metal as disclosed herein) is coated with a carbon allotrope or any combination thereof (i.e., graphene, few-layer graphene, nano-graphite particles, graphite, or carbon nano-tubes).

The coated metal pieces are assembled into a rod or billet for extrusion.

The precursor material is extruded (typically at elevated temperatures) to consolidate the material, refine the microstructure, and develop electrical coherency between the copper matrix and carbon allotrope(s), to produce a composite or alloy that demonstrates enhanced electrical and thermal properties.

The amount of quality carbon allotrope that can be introduced into the metal matrix, in the manner that is necessary (i.e., coherency, refinement, and orientation) using this solid-state approach is limited, and this limits the properties that can be achieved. Hence, this material will undergo further processing such as rolling, annealing, and recoating with aforementioned carbon allotropes. This material will then be assembled into another extrusion billet/rod for re-extrusion.

Re-processing will continue until the requisite amount of carbon allotrope has been achieved, with the requisite amount of refinement, coherency and orientation, to achieve the electrical (and/or thermal) properties that are desired, such that the ultra-conductive metal composite has a mono-layer of graphene or few layer (e.g., three-layer) graphene.

More specifically, using the process shown in FIG. 5, high quality graphene as monoatomic films with macro-scale lateral dimensions deposited on copper foil will be produced. The graphene is deposited on the copper using any suitable deposition process. For example, CVD on copper produces graphene that is more than 95% mono-layer.

The graphene exhibits a polycrystalline structure with an average grain size of 20 μm and grain boundaries comprised mainly of pentagon-hexagon or heptagon-hexagon pairs and dislocations. The sheets demonstrate an average electrical resistance of 450 Ω/sheet, and electron mobility in the range of 6900 cm²/V·s.

Preparation of the precursor material involved mechanically transferring the graphene onto the copper foil to achieve desired graphene concentrations in the bulk processed wire. This is a step to achieve simultaneously the desired quantity, distribution, and electrical interfacial coherency within the copper matrix. Regardless, this will be held to no more than 3 layers of the graphene.

To ensure graphene quality consistency, specifically defect density which is determined using Raman spectra and kept below a predetermined threshold. Defect density below about 2.1±0.1×10¹⁰ cm⁻² is consistent with that of high purity graphene. Defect density is calculated from the intensities of Raman spectra's D-peak (I_{D}) and G-peak (I_{G}) with the assumption that the distance between defects in the material (L_{D}) was greater than 10 nm. A spectrum's D, G, and 2D graphene intensity peaks correspond to 1350 cm⁻¹, 1580 cm⁻¹, and 2700 cm⁻¹ wavelengths. The D-peak is used to characterize the number of defects in graphene and the G-peak is used to characterize the amount of sp² bonding present in the graphene. A higher G-peak reading corresponds to a more perfect graphene lattice, free of defects. The 2D-peak is indicative of the number of graphene layers, in that more graphene layers change the intensity and spread of the 2D peak. Equation (1) is used to calculate L_{D} and this was determined to be about 18 nm to 39 nm:

$${L}_{D} = \sqrt{\frac{4.3 \times {10}^{3}}{{E}_{L}^{4}} {( \frac{{I}_{d}}{{I}_{G}} )}^{- 1}} . \qquad ( Equation 1 )$$

where E_{L} is the laser excitation energy in eV (2.33 eV). The intensity ratios of the D- and G-peaks along with the laser wavelength (λ_{L}) were used in Equation (2) to determine the defect density (n_{D}) of the graphene samples. The empirical formulae were then subsequently used to find the defect density based on I_{D}/I_{G} as outlined in Equation (2):

$${n}_{D} = \frac{1.8 \times {10}^{3}}{{λ}_{L}^{4}} ( \frac{{I}_{D}}{{I}_{G}} ) , \qquad ( Equation 2 )$$

where λ_{L} is the Raman spectroscope laser wavelength corresponding to 532 nm.

Billet assembly involves the graphene coated foils to be appropriately sectioned, oriented, and assembled into billet pre-forms for hot pressing and subsequent hot extrusion.

Fabricated graphene/copper billet pre-forms are hot-extruded. The (for example, rod-sized) billet is extruded into a bulk form, via a process called Hot Extrusion Alloying or the HEA process, since the copper is not effectively alloyed until undergoing this process. Extrusion takes place at temperatures of 700-800° C. using specialty tooling appropriately designed for this purpose. PIO controlled electric heaters are used to maintain apparatus temperatures using K-type thermocouples at key locations. A thermocouple at the die entrance provides the effective extrusion temperature. Accommodations are made for extrudate cooling and oxide prevention during processing at the elevated temperatures.

In situ pressing will precede HEA, which can proceed at a relatively slow speed. The extrusion ratio (ratio of the container bore area to the extrudate area) are in the range of 20-100. The first extrusion sequence(s) will not result in a wire form, but of a profile that is conducive to post-extrusion cold rolling into suitable sheet dimensions. A practical limit for graphene concentration is encountered with the previous HEA approach due to minimum copper foil thickness and maximum number of graphene layers possible (or practical) on the copper foil. According to the present disclosure, a graphene concentration in the copper matrix is increased by an iterative sequence of HEA, and then rolling the extrudate into sheets that re-coated with CVD graphene, to be re-processed into billet performs for re-extrusion. This will be repeated until the desired graphene concentration is achieved to meet the 109% IACS goal. Electrical conductivity will be measured at each step to assess the conductivity trend and adjust the targeted graphene concentration as required.

During each re-processing, the graphene becomes more uniformly distributed, with the desired (axial) orientation and copper-graphene interface refinements. Inherent gradual plastic shear stresses within the deformation zone can promote exfoliation of any multi-layers, thereby fostering mono-layer graphene, while minimizing graphene damage. This processing sequence can be highly automated to reduce manufacturing costs.

To achieve 109% IACS, the final extrusion step will be of a wire form, for example a 2 mm diameter wire, 300 mm in length (the final wire diameter may be decreased to 1 mm to minimize material costs in this effort). Drawing (such as conventional drawing) can be employed to produce wire at the standard AWG (American Wire Gauge) sizes tolerances.

Cold rolling and graphene re-coating intermediate steps can achieve higher graphene concentrations with HEA solid state processing. To increase the level of graphene in the copper matrix, the copper-graphene extrudate (profile) is rolled into a sheet that is then re-coated with high-quality graphene and then re-processed via the Billet Assembly and Hot Extrusion steps already discussed. This process is repeated until the desired graphene concentration (or properties) are achieved. Fully recrystallized, annealed structure in the copper nano-alloy exhibits exceptional ductility and formability characteristics, dominated by the copper matrix and low graphene content. Copper can generally be cold worked to substantial area reductions (>90%) before annealing is required, however an intermediate anneal may be necessary if roll forces are too high to achieve the final thickness.

The microstructure developed during HEA and then subsequent reprocessing is vital to the physical and electrical properties of the bulk material. Previous (one-pass) HEA copper-graphene wire exhibited reasonably equi-axed and uniform recrystallized grains with negligible porosity, consistent with wrought Cu produced via hot deformation. The microstructure of the material (and electrical properties) after complete synthesis through HEA shows effective integration of graphene into copper. It does this while avoiding the issues typically observed in copper-graphene composites, namely agglomerations, damaging the graphene during material synthesis thereby reducing electrical properties, and introducing porosity and oxidation of the copper. Carbon forms no intermediate phases with copper and is essentially insoluble, particularly at HEA temperatures. The final material can be described as a two-phase Cu—C nano-alloy, where the alloying phase in the FCC copper matrix is hexagonal graphene crystals.

During HEA and re-processing, the polycrystalline graphene grain boundaries can fracture into smaller graphene-particles, due to the applied stresses. Fracture typically occurs at graphene grain boundaries and at defects. Simultaneously, competing kinetic mechanisms of dynamic recovery, dynamic recrystallization, post-dynamic recrystallization, and grain growth produce the final micro (and nano) structure(s). Recrystallization minimizes the free-energy associated with crystal distortion, and in immiscible binary systems such as this, the graphene may well manifest predominantly at the boundaries of copper grains which can nucleate at the graphene surfaces. Thus, a reduction of electron scattering at grain boundaries can be one mechanism enhancing electrical properties. The copper grains can also recrystallize around the graphene during HEA processing. Thus, redistribution of graphene during re-processing and re-extrusion in concert with kinetic processes are expected provide additional refinements and benefits.

The wire (and ultimately rod) form of ultra-conductive material will eventually be processed by conventional wire drawing and annealing to AWG specifications. The material at this stage of production is essentially in a state that can be processed by established high volume process technologies already in existence, which includes wire drawing, annealing, stranding and insulation coating.

These processes and steps according to the present disclosure can be applied and adapted to metals other than copper, such as aluminum, silver, magnesium, or other suitable metal. Accordingly, the processes and steps herein disclosed are not limiting, as will be appreciated by one skilled in the art.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various embodiments, are intended to indicate that such embodiments are possible examples, representations, and/or illustrations of possible embodiments (and such terms are not intended to connote that such embodiments are necessarily extraordinary or superlative examples).

The term “coupled,” as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. Such members may be coupled mechanically, electrically, and/or fluidly.

The term “or,” as used herein, is used in its inclusive sense (and not in its exclusive sense) so that when used to connect a list of elements, the term “or” means one, some, or all of the elements in the list. Conjunctive language such as the phrase “at least one of X, Y, and Z,” unless specifically stated otherwise, is understood to convey that an element may be either X, Y, Z; X and Y; X and Z; Y and Z; or X, Y, and Z (i.e., any combination of X, Y, and Z). Thus, such conjunctive language is not generally intended to imply that certain embodiments require at least one of X, at least one of Y, and at least one of Z to each be present, unless otherwise indicated.

References herein to the positions of elements (e.g., “top,” “bottom,” “above,” “below,” etc.) are merely used to describe the orientation of various elements in the FIGURES. It should be noted that the orientation of various elements may differ according to other exemplary embodiments, and that such variations are intended to be encompassed by the present disclosure.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It is important to note that the disclosure as shown in the various exemplary embodiments is illustrative only. Additionally, any element disclosed in one embodiment may be incorporated or utilized with any other embodiment disclosed herein. Although only one example of an element from one embodiment that can be incorporated or utilized in another embodiment has been described above, it should be appreciated that other elements of the various embodiments may be incorporated or utilized with any of the other embodiments disclosed herein.

1. A conductor material comprising:
a metal matrix; and
a first carbon allotrope distributed within the metal matrix, the first carbon allotrope being aligned with a direction of electric current flow through a length of the metal matrix,
wherein the metal matrix and the first carbon allotrope have an electrical interfacial coherency.

2. The conductor material according to claim 1, wherein a defect density of the first carbon allotrope is less than a predetermined threshold.

3. The conductor material according to claim 2, wherein the predetermined threshold is about 2.1±0.1×10¹⁰ cm⁻².

4. The conductor material according to claim 3, wherein the predetermined threshold of the defect density is measured across the length of the metal matrix.

5. The conductor material according to claim 1, wherein the metal matrix comprises a metal selected from the following group: copper, aluminum, silver, or magnesium.

6. The conductor material according to claim 1, wherein the first carbon allotrope is selected from the following group: graphene, few-layer graphene, nano-graphite particles, graphite, or carbon nano-tubes.

7. The conductor material according to claim 1, wherein a concentration of the first carbon allotrope of the conductor material is within a range of about 0.004 to about 0.016 weight percent.

8. The conductor material according to claim 1, further comprising a second carbon allotrope distributed within the metal matrix,
wherein the second carbon allotrope is selected from the following group: graphene, few-layer graphene, nano-graphite particles, graphite, or carbon nano-tubes.

9. The conductor material according to claim 8, wherein a concentration of the second carbon allotrope of the conductor material is within a range of about 0.004 to about 0.016 weight percent.

10. The conductor material according to claim 8, wherein the first carbon allotrope is different from the second carbon allotrope.

11. The conductor material according to claim 1, wherein the first carbon allotrope comprises a polycrystalline structure having an average grain size of about 20 μm.

12. The conductor material according to claim 1, wherein the first carbon allotrope comprises hexagonal graphene crystals.

13. The conductor material according to claim 1, wherein the metal matrix comprises metallic grains recrystallized to one or more first carbon allotrope particles.

14. The conductor according to claim 1, wherein the electrical interfacial coherency is more than a predetermined threshold.

15. A copper composite material comprising:
a copper matrix; and
a graphene coat deposited on the copper matrix, the graphene coat forming an electrical interfacial coherency with the copper matrix,
wherein the graphene coat comprises graphene particles aligned with a direction of electric current flow along a length of the copper wire,
wherein a defect density of the graphene particles is less than about 2.1±0.1×10¹⁰ cm⁻², and
wherein the graphene particles comprises grain boundaries having a polycrystalline structure,
wherein the graphene coat comprises graphene and a carbon allotrope selected from the following group: graphene, few-layer graphene, nano-graphite particles, graphite, or carbon nano-tubes.

16. The copper composite material according to claim 15, wherein the polycrystalline structure comprises at least one pentagon-hexagon pair.

17. The copper composite material according to claim 15, wherein the polycrystalline structure comprises at least one heptagon-hexagon pair.

18. A method for making an ultra-conductive metal composite, the method comprising the steps of:
(a) providing a metal component;
(b) coating the metal component with a carbon allotrope;
(c) combining a plurality of coated metal components to form a billet assembly;
(d) hot extruding the billet assembly to form a composite strip;
(e) rolling the composite strip; and
(f) extruding the composite strip to form a final metal composite.

19. The method according to claim 18, wherein the step of coating the metal wire with a carbon allotrope is by a deposition process.

20. The method according to claim 18, further comprising a step (g) after step (f), step (g) comprising further processing of the final metal composite.
